(19) United States
(12) Patent Application Publication
(10) Pub. No.: US 2011/0041888 A1
(43) Pub. Date: Feb. 24, 2011

(54) INSULATING CONSTRUCTION PANEL WITH PHOTOVOLTAIC MODULE

(76) Inventor: Bart Levine, Mountain Lakes, NJ (US)

Correspondence Address: DYKAS & SHAVER LLP, P.O. BOX 877, BOISE, ID, 83701-0877, US

(21) Appl. No.: 12/545,533

(22) Filed: Aug. 21, 2009

(51) Int. Cl. H01L 31/042

(52) U.S. Cl. 136/244

(57) ABSTRACT

Disclosed is an insulating construction and solar panel comprising an insulating core that defines at least one opening. A rigid skin covers the insulating core and defines a ridge extending along a first edge and a channel extending along a second edge. A crystalline photovoltaic module is fitted within the opening, and a translucent pane covers the outer surface of the crystalline photovoltaic module. The insulating construction and solar panel is configured to connect to a second and third insulating construction and solar panel by interconnecting the corresponding ridges and channels.

### FIELD OF THE INVENTION

The present insulating construction panel with photovoltaic module relates generally to solar electricity generation and more specifically to the integration of solar-electricity-generating modules into structures.

### BACKGROUND OF THE INVENTION

Photovoltaic modules are used to generate usable power from solar energy. Use of such modules to provide power to structures, such as homes and office buildings, has become very popular. However, installing photovoltaic modules to pre-existing structures is often expensive and time consuming. Further, installing photovoltaic modules to structures can lead to leaks at mounting points, particularly when the photovoltaic modules are mounted to roofs, and can require the installation of additional structural support, given the heft of the photovoltaic module installed. The bulkiness of traditional crystalline photovoltaic modules is also undesirable and unattractive. Such bulky installations on roofs can further inhibit snow shedding, raising the risk that snow will accumulate undesirably and lead to roof damage or collapse.

Thin film type solar cells have been successfully mounted to structures, such as roofs, and have the benefit, as compared to traditional crystalline photovoltaic modules, of being less bulky and therefore more aesthetically pleasing. However, thin film type solar cells are less efficient in solar power generation than the traditional crystalline photovoltaic modules. Further, like crystalline photovoltaic modules, the thin film type solar cells still require installation onto a pre-existing structure, such as a roof, and therefore raise the risk of leaks and other structural damage.

Structures can now be constructed quickly by interlocking pre-fabricated, metal construction panels. This is particularly useful in roof construction. Metal roofing is often long lasting, light weight, easy and fast to install, and fire proof. Pre-fabricated panels install simply and quickly with minimal on-site hassle and waste of material. Such pre-fabricated panels eliminate the need to fit eave linings, plasterboard, battens, insulation lining, roof sheeting, and painting. Use of pre-fabricated metal panels can cut installation times in half compared to traditional built-up alternatives. They also allow for improved spanning and cantilever capabilities and reduce the need for expensive support structures such as roof trusses and support beams. Often, such pre-fabricated, metal construction panels will include surface skins bonded to an internal core so as to reduce the risk of wrinkling and to improve the strength of the panel overall. However, while the use of pre-fabricated metal panels reduces the overall cost of construction of roofs and other structures, adding solar panels to such structures has still required the mounting of separate solar panel modules. These installations lead to the same problems found with installing solar panels to more traditionally-constructed structures.

### SUMMARY OF THE INVENTION

Described herein is an insulating construction and solar panel in which a crystalline photovoltaic module is fitted within an opening in an insulating core that is covered by a rigid skin. A translucent pane covers the outer surface of the crystalline photovoltaic module, and the translucent pane is sealed to the rigid skin so that the crystalline photovoltaic module is protected from environmental elements. The insulating construction and solar panel is preferably pre-fabricated before transport to a construction site, and installation requires little more than interconnecting one panel to another. This reduces the overall cost and time of construction. Further, because the crystalline photovoltaic module is fitted within the insulating core of the panel, the need for separate installation of a solar panel to the structure is eliminated, and the construction panel need not be separately insulated during installation. Fitting the crystalline photovoltaic module within the insulating core of the panel further provides the aesthetic benefits of a thin photovoltaic module installation with the improved power-generation efficiency of a crystalline photovoltaic module. Also, because the crystalline photovoltaic module is sealed within the panel during initial fabrication, the panel is not made vulnerable to leaks in the way that a later-installed, separate solar panel is.

Preferably, the insulating construction and solar panel is pre-fabricated, i.e., fabricated so as to fit the crystalline photovoltaic module within the insulating core and to seal the unit before the panel is installed onto or in a structure. As such, at the time of installation on, in, or to a structure, the insulating construction and solar panel can be quickly installed. By installing only the insulating construction and solar panel, therefore, the structure is provided with a roofing or siding panel, as the case may be, that is already insulated and already fitted with solar energy generation capability.

In more particularity, the insulating construction and solar panel comprises an insulating core covered by a rigid skin. The material used as the insulating core depends, largely, on the expected environmental conditions in which the insulating construction and solar panel is to be installed. Insulating material suitable for high temperatures, such as spun glass or rock wool, may be necessary in the hotter environments. In some embodiments, the insulating core comprises layers of various insulating materials rather than a single insulating material or a uniform insulating material.

The rigid skin covering the insulating core is preferably a strong metal. The rigid skin defines, along a first edge, a ridge and, along a second edge, a channel. Preferably, the first and seconed edges are the side edges of the rigid skin, rather than the top or bottom edges. However, in some embodiments, the first edge is the top or bottom edge, and the second edge is the bottom or top edge, respectively. In still other embodiment, each edge of the rigid skin defines either a ridge or a channel. Each ridge is configured to interconnect with the channel of another construction panel. As such, during construction, the insulating construction and solar panel is interconnected with another construction panel, which may be another insulating construction and solar panel, by joining the ridge of the first panel with the channel of the second panel. The insulating construction and solar panel can then be interconnected on the other side with a third construction panel, which, again, may be another insulating construction and solar panel, by joining the channel of the first panel with the ridge of the third panel. In the embodiments in which each edge of the rigid skin defines either a ridge or a channel, the insulating construction and solar panel can be interconnected with other panels on all edges.

The insulating core defines an opening into which a crystalline photovoltaic module is fitted. Preferably, the shape of the opening conforms to the shape of the crystalline photovoltaic module. In some embodiments, the opening extends all the way through the insulating core, such that the inner surface of the crystalline photovoltaic module is exposed to the interior of the structure. This embodiment is ideal for warmer environments, so that the inner surface of the crystalline photovoltaic module is well ventilated, thus minimizing the risk that the crystalline photovoltaic module will overheat or reach temperatures at which the crystalline photovoltaic module is inefficient in its solar-energy-to-power generation.

In other embodiments, the opening into which the crystalline photovoltaic module is fitted does not extend all the way through the insulating core, such that the inner surface of the crystalline photovoltaic module remains covered and insulated by the insulating core and is not exposed to the interior of the structure. This embodiment is ideal for colder environments, so that the interior of the structure is insulated as is the inner surface of the crystalline photovoltaic module.

In still other embodiments, the insulating construction and solar panel further includes at least one adjustable insulating shutter. Each shutter comprises an insulating material, preferably the same material used to form the insulating core. Each shutter is configured to be selectively moved from a closed position, in which the shutter covers and insulates the inner surface of the crystalline photovoltaic module, to any of a number of open positions, in which the inner surface of the crystalline photovoltaic module is at least partially uncovered. The shutters are further configured to be selectively moved from any open position to another open position or to the closed position.

In the open positions, the inner surface of the crystalline photovoltaic module is more exposed to the interior of the structure and more exposed to ventilation than it is when the shutter is in the closed position. Thus, the open positions accommodate cooling of the module so as to keep the crystalline photovoltaic module in temperature ranges conducive to the high solar-energy-to-power generation efficiency. The adjustable insulating shutters may further be moved so as to allow heat from the crystalline photovoltaic module to contribute to heating of the interior of the structure in which the insulating construction and solar panel is installed.

In some configurations, the shutters are pivotally connected to the insulating core such that moving from one position to another is accomplished through pivoting the shutter further to or farther away from the inner surface of the crystalline photovoltaic module. In some of these configurations, the shutters are manually movable, and, in other configurations, the insulating construction and solar panel further includes a temperature sensor and an actuator to allow for automatic adjustment of the position of the shutter so as to allow more or less ventilation to the inner surface of the crystalline photovoltaic module. That is, when the temperature sensor detects that the temperature of the crystalline photovoltaic module is less than a pre-determined minimum temperature, the actuator automatically moves the shutter to the closed position. When the temperature sensor detects that the temperature of the crystalline photovoltaic module is greater than a pre-determined maximum temperature, the actuator automatically moves the shutter to an open position.

It is preferred that the insulating construction and solar panel includes at least one crystalline photovoltaic module. In certain embodiments, the insulating construction and solar panel will include a plurality of crystalline photovoltaic modules.

The purpose of the Summary is to enable the public, and especially the scientists, engineers, and practitioners in the art who are not familiar with patent or legal terms or phraseology, to determine quickly from a cursory inspection, the nature and essence of the technical disclosure of the application. The Summary is neither intended to define the insulating construction and solar panel, which is measured by the claims, nor is it intended to be limiting as to the scope of the insulating construction and solar panel in any way.

Still other features and advantages of the claimed insulating construction and solar panel will become readily apparent to those skilled in this art from the following detailed description describing preferred embodiments thereof, simply by way of illustration of the best mode contemplated by carrying out the insulating construction and solar panel. As will be realized, the insulating construction and solar panel is capable of modification in various obvious respects all without departing from the same. Accordingly, the drawings and description of the preferred embodiments are to be regarded as illustrative in nature, and not as restrictive in nature.

### BRIEF DESCRIPTION OF THE DRAWINGS

FIG. 1 is a perspective view of the top side, front side, and right side of an insulating construction and solar panel according to a first, second, and third embodiment.

FIG. 2 is a partial, perspective view of the top side, front side, and right side of the insulating core of the insulating construction and solar panel according to the first and second embodiments.

FIG. 3 is a partial, perspective view of the top side, front side, and right side of the insulating construction and solar panel according to the first and third embodiments, with the translucent pane removed.

FIG. 4 is a partial, perspective view of the top side, front side, and right side of the insulating construction and solar panel according to the first embodiment, with the crystalline photovoltaic module removed.

FIG. 5 is a perspective view of the bottom side, front side, and left side of an insulating construction and solar panel according to a second embodiment in an open position.

FIG. 6 is a perspective view of the bottom side, front side, and left side of an insulating construction and solar panel according to the second embodiment in a closed position.

FIG. 7 is a sectional, elevation view of the insulating construction and solar panel according to the first embodiment depicted in FIG. 1, taken along plane A, as indicated.

FIG. 8 is a perspective view of the bottom side, front side, and left side of an insulating construction and solar panel according to a third embodiment.

### DESCRIPTION OF THE PREFERRED EMBODIMENTS

While the insulating construction and solar panel is susceptible to various modifications and alternative constructions, certain illustrated embodiments thereof have been shown in the drawings and will be described below in detail. It should be understood, however, that there is no intention to limit the insulating construction and solar panel to the specific form disclosed, but, on the contrary, the insulating construction and solar panel is to cover all modifications, alternative constructions, and equivalents falling within the spirit and scope of the insulating construction and solar panel as defined in the claims.

In the following description and in the figures, like elements are identified with like reference numerals. The use of “e.g.,” “etc,” and “or” indicates non-exclusive alternatives without limitation unless otherwise noted. The use of “including” means “including, but not limited to,” unless otherwise noted.

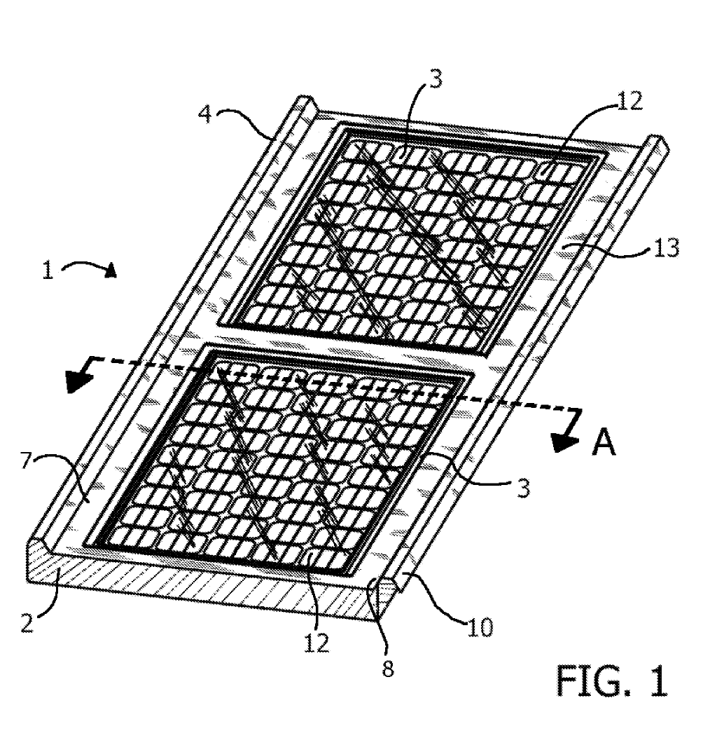

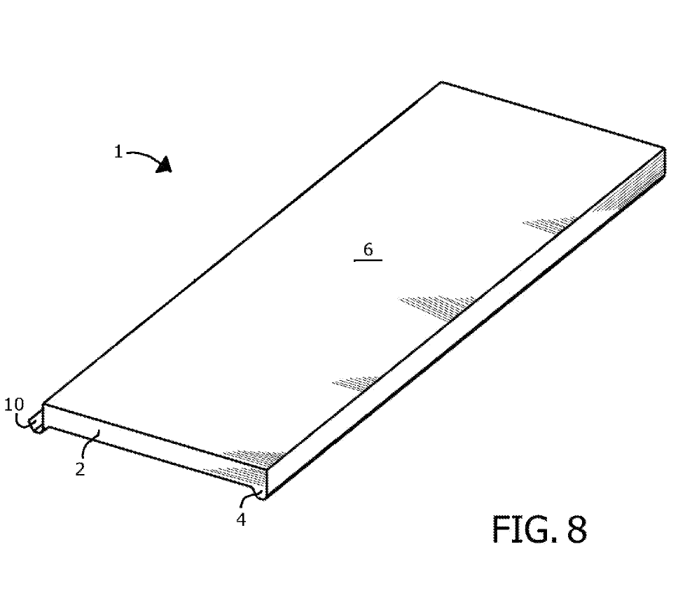

As shown in FIGS. 1 through 8, the insulating construction and solar panel 1 comprises an insulating core 2 that is covered by a rigid skin 13. Preferably, the rigid skin 13 is adhered to the top surface 5 of the insulating core 2 so as to discourage shifting of the rigid skin 13 relative to the insulating core 2 and so as to discourage warping, wrinkling, buckling, or shifting of the rigid skin 13. In some embodiments, a second rigid skin covers and is adhered to the bottom surface 6 of the insulating core 2 so as to provide further support and rigidity to the insulating construction and solar panel 1.

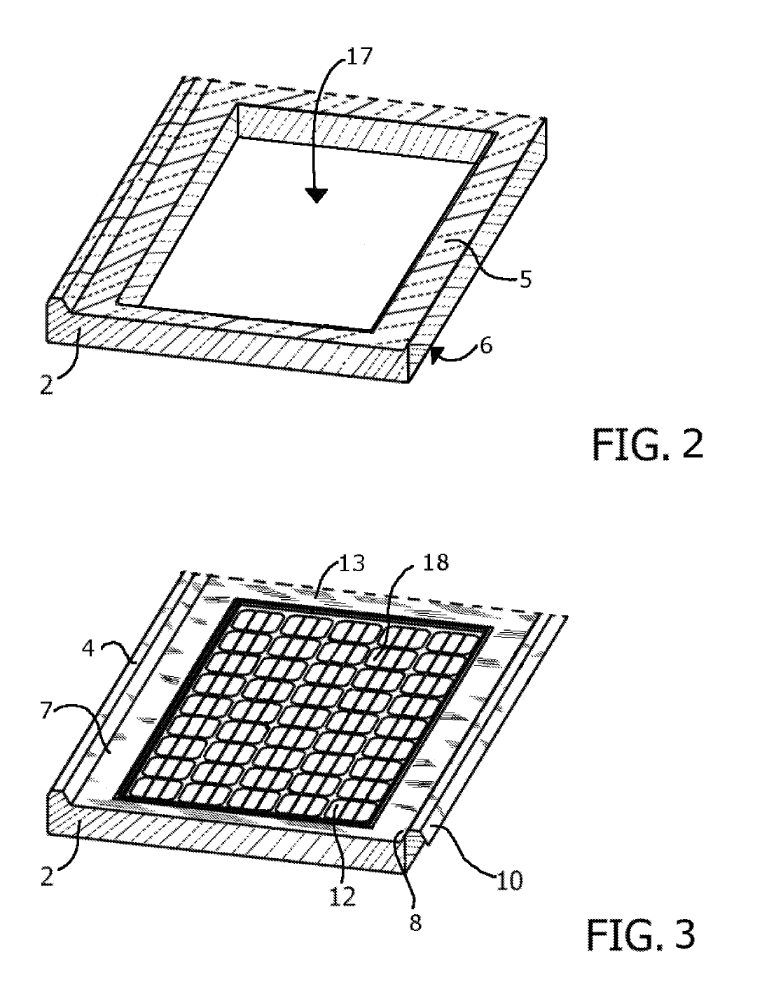

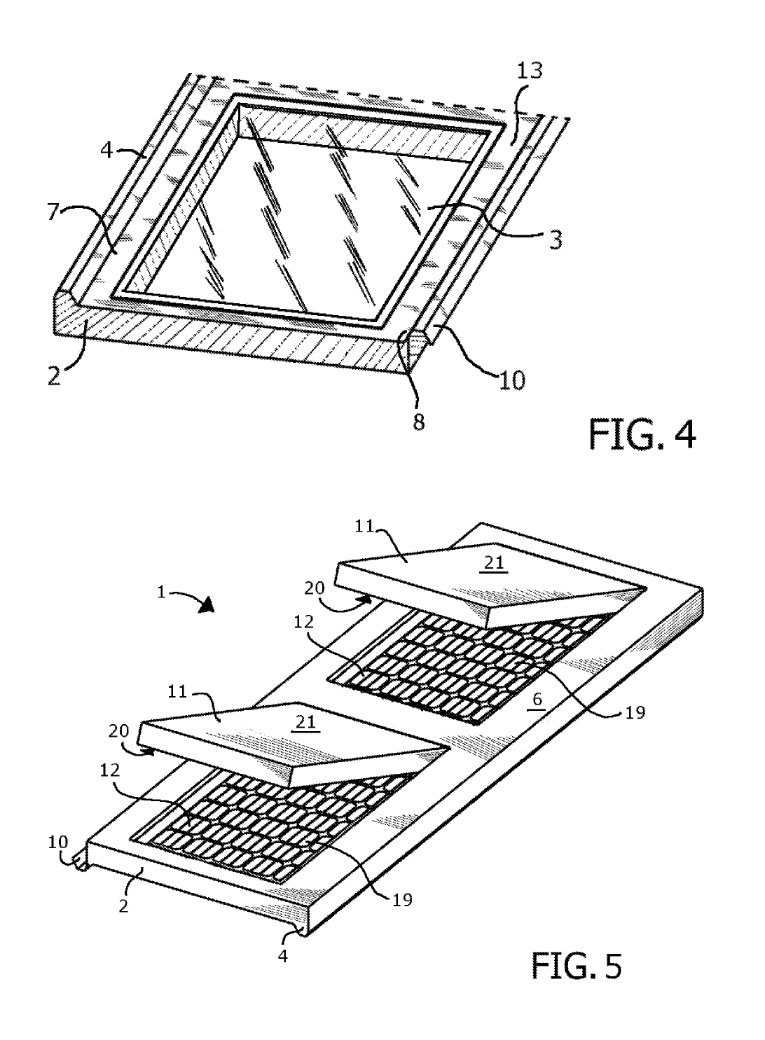

The insulating core 2 and rigid skin 13 define at least one opening 17 (FIG. 2) into which is fitted a crystalline photovoltaic module 12 (FIG. 3). Alternatively, the insulating core 2 defines at least one opening 17 and the rigid skin 13 covering the insulating core 2 conforms to the surface shape of the insulating core 2 as shown in FIG. 4.

The crystalline photovoltaic module 12 has an outer surface 18 and an inner surface 19. A translucent pane 3 (FIG. 4) covers the outer surface 18 of the crystalline photovoltaic module 12. The outer surface 18 of the crystalline photovoltaic module 12 is arranged so as to receive sun light and thereby facilitate the transmission of solar-generated energy by the crystalline photovoltaic module 12. Thus, the top surface shown in FIG. 1 is preferably the surface directed outward of the structure in which the insulating construction and solar panel 1 is incorporated.

The insulating core 2 has a top surface 5 (FIG. 2) and bottom surface 6 (FIGS. 5, 6, and 8). In some embodiments, the crystalline photovoltaic module 12 is fitted within the opening 17 of the insulating core 2 such that the outer surface 18 of the crystalline photovoltaic module 12 is essentially flush with the top surface 5 of the insulating core 2. In other embodiments, the crystalline photovoltaic module 12 is fitted within the opening 17 of the insulating core 2 such that the outer surface 18 of the crystalline photovoltaic module 12 is essentially flush with the rigid skin 13. In still other embodiments, such as that shown in FIG. 7, the crystalline photovoltaic module 12 is fitted within the opening 17 of the insulating core 2 such that the outer surface 18 of the crystalline photovoltaic module 12 is recessed from both the top surface 5 of the insulating core 2 and the rigid skin 13. Preferably, in such embodiments, the crystalline photovoltaic module 12 further includes a top flange 15 along the outside of the outer surface 18 and an bottom flange 14 along the outside of the inner surface 19. The top flange 15 and the bottom flange 14 extend into the insulating core 2 and hold the crystalline photovoltaic module 12 in place within the insulating core 2. Also preferably, the bottom flange 14 and top flange 15 form a hermetic seal between the insulating core 2 and crystalline photovoltaic module 12.

Preferably, and as shown in FIGS. 4 and 7, the translucent pane 3 covering the outer surface 18 of the crystalline photovoltaic module 12 overlaps, to some extent, the surrounding rigid skin 13 such that the translucent pane 3 and the rigid skin 13 are attached via a lap joint 9. It is further preferred that the translucent pane 3 be hermetically sealed to the rigid skin 13 so has to protect the insulating core 2 from environmental elements, such as rain, snow, dirt, and dust. In other embodiments, the rigid skin 13 overlaps the translucent pane 3 such that the outer edge of the translucent pane 3 is sealed between the underside of the rigid skin 13 and the top surface 5 of the insulating core 2. Again, it is preferred that there is a hermetic seal between the rigid skin 13 and the translucent pane 3.

The rigid skin 13 has a first edge 7 and a second edge 8. It defines a ridge 4 along the first edge 7 and a channel 10 along the second edge 8. In other embodiments, the top and bottom edges of the rigid skin 13 also define either a channel 10 or ridge 4. In still other embodiments, the first and second edges 7, 8 of the rigid skin 13 each define a ridge 4, while the first and second edges 7, 8 of a second panel's rigid skin 13 each define a channel 10. Each ridge 4 is configured to interlock with a channel 10 of a separate insulating construction and solar panel 1 or other construction panel. Likewise, each channel 10 is configured to interlock with a ridge 4 of another separate insulating construction and solar panel 1 or other construction panel. As such, the insulating construction and solar panel 1 can be attached to other construction panels by interlocking channels 10 and ridges 4. Specifically, the insulating construction and solar panel 1 can be attached to a second construction panel having a matching second ridge by interconnecting the channel 10 with the second ridge of the second construction panel. A third construction panel that has a matching third channel can then be attached to the insulating construction and solar panel 1 by interconnecting the third channel with the ridge 4. Preferably, each ridge 4 is shaped to coordinate with the shape of each channel 10. As such, insulating construction and solar panels 1 are readily connectable during construction. Each insulating construction and solar panel 1 may alternatively be connected to any panel having a coordinating ridge or channel. As such, the insulating construction and solar panel 1 is not limited to being installed with only other like insulating construction and solar panels.

It is further preferred that the insulating core 2 also define a ridge along one side, as shown in FIGS. 2 and 7, so that the insulating core 2 will conform to the shape of the ridge 4 of the rigid skin 13 as shown in FIG. 7. In some embodiments, such as that shown in FIG. 7, the insulating core 2 further defines an elevated area along its other side so as to conform to the attached side of the channel 10 of the rigid skin 13. Preferably, the majority of the channel 10 overhangs the insulating core 2 so as to be readily accessible for connection to the ridge of another construction panel.

According to the first embodiment, depicted in FIGS. 1 through 4 and 7, the opening 17 defined by the insulating core 2 extends from the top surface 5 of the insulating core 2 through to the bottom surface 6 as shown in FIGS. 2 and 4. The crystalline photovoltaic module 12, fitted within the insulating core 2, therefore, is non-insulated at its outer surface 18 and inner surface 19. Such an embodiment would be preferable in warmer environments as the non-insulated inner surface 19 can be ventilated from being exposed to the interior of the structure in which it is incorporated. In some such embodiments, the height of the crystalline photovoltaic module 12 essentially matches the height of the insulating core 2, such that, when the crystalline photovoltaic module 12 is fitted within the opening 17 of the insulating core 2, the outer surface 18 of the crystalline photovoltaic module 12 is essentially flush with the top surface 5 of the insulating core 2 and the inner surface 19 of the crystalline photovoltaic module 12 is essentially flush with the bottom surface 6 of the insulating core 2. In other such embodiments, like that depicted in FIG. 7, the height of the crystalline photovoltaic module 12 is less than that of the insulating core 2, and the insulating core 2 is fitted within the opening 17 of the insulating core 2 such that the inner surface 19 is recessed within the insulating core 2, leaving an open volume 16.

According to the third embodiment, depicted in FIGS. 1, 3, and 8, the opening 17 defined by the insulating core 2 extends from the top surface 5 into the interior of the insulating core 2, but not through to the bottom surface 6. As such, when the crystalline photovoltaic module 12 is fitted within the insulating core 2, the inner surface 19 is covered and therefore insulated by the insulating core 2. Such an embodiment would be preferably in cooler environments where overheating of the crystalline photovoltaic module 12 is not a large concern.

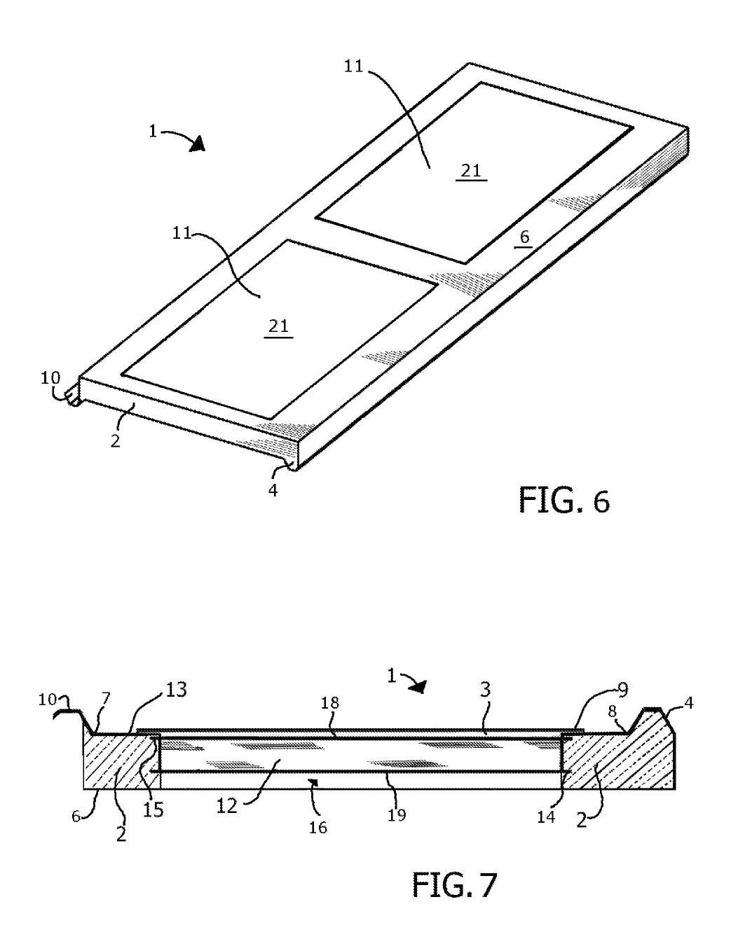

According to the second embodiment, depicted in FIGS. 1 through 3, 5 and 6, the insulating construction and solar panel 1 further includes at least one adjustable insulating shutter 11 connected to the insulating core 2. The adjustable insulating shutter 11 is configured so that it can be selectively moved from a closed position, such as that shown in FIG. 6, to at least one open position, such as that shown in FIG. 5. In the closed position (FIG. 6), the adjustable insulating shutter 11 covers and insulates the inner surface 19 of the crystalline photovoltaic module 12. Thus, the closed position (FIG. 6) is ideal for use during instances of cooler environmental conditions. In the open positions, such as that shown in FIG. 5, the inner surface 19 of the crystalline photovoltaic module 12 is at least partially uncovered so as to leave the inner surface 19 of the crystalline photovoltaic module 12 at least partially exposed. The open positions are ideal for use during instances of warmer environmental conditions, so that the inner surface 19 of the crystalline photovoltaic module 12 may be ventilated to reduce the temperature of the crystalline photovoltaic module 12 and thereby accommodate high efficiency in the solar-energy-to-power generation. The degree to which the adjustable insulating shutter 11 is positioned away from the inner surface 19 of the crystalline photovoltaic module 12, i.e., the amount to which the inner surface 19 is uncovered and therefore exposed, is dependent upon the desired amount of ventilation to the inner surface 19. The less the amount of ventilation and cooling to the inner surface 19 desired, the closer to the inner surface 19 the adjustable insulating shutter 11 is positioned.

In some configurations of the third embodiment, the position of the adjustable insulating shutter 11 is adjusted manually, such as through a crank or by otherwise physically moving the adjustable insulating shutter 11. In other configurations, the position of the adjustable insulating shutter 11 is adjusted automatically as adjustment is needed. In these embodiments, the insulating construction and solar panel 1 further includes a temperature sensor and an actuator. The temperature sensor is configured to detect the temperature of the crystalline photovoltaic module 12. The actuator is configured to move the adjustable insulating shutter 11 to its closed position (FIG. 6) when the temperature sensor detects that the temperature of the crystalline photovoltaic module 12 is lower than a pre-determined minimum temperature. As such, the adjustable insulating shutter 11 will be moved to the position in which the adjustable insulating shutter 11 insulates the inner surface 19 of the crystalline photovoltaic module 12 and where the interior of the structure will be further insulated. The actuator is further configured to move the adjustable insulating shutter 11 to an open position, such as that shown in FIG. 5, when the temperature sensor detects that the temperature of the crystalline photovoltaic module 12 is higher than a pre-determined maximum temperature. As such, the adjustable insulating shutter 11 will be moved to a position in which the adjustable insulating shutter 11 at least partially uncovers the inner surface 19 of the crystalline photovoltaic module 12 and therefore exposes the inner surface 19 to ventilation so as to allow the crystalline photovoltaic module 12 to be cooled and return to temperatures ranges conducive for high solar-energy-to-power-generation efficiency.

According to this second embodiment, depicted in FIGS. 1 through 3, 5, and 6, each adjustable insulating shutter 11 is pivotally connected to the insulating core 2 and is selectively pivotally movable from the closed position (FIG. 6) to any open position, including that shown in FIG. 5, and vice-versa. Such pivotal connection can be incorporated in embodiments configured for manual adjustment of the adjustable insulating shutter 11 or automatic adjustment of the adjustable insulating shutter 11.

According to this second preferred embodiment, the height of the crystalline photovoltaic module 12 is less than the height of the insulating core 2, and the crystalline photovoltaic module 12 is fitted within the opening 17 of the insulating core 2 such that the inner surface 19 of the crystalline photovoltaic module 12 is recessed within the insulating core 2, thus leaving an open volume 16 (like that shown in FIG. 7 when no adjustable insulating shutter 11 is in place). Preferably, the height of the adjustable insulating shutter 11, i.e., the measured distance from the shutter top surface 20 and shutter bottom surface 21, corresponds to the height of the open volume 16 such that when the adjustable insulating shutter 11 is positioned in the closed position (FIG. 6), the shutter bottom surface 21 is essentially flush with the bottom surface 6 of the insulating core 2.

The exemplary embodiments shown in the figures and described above illustrate but do not limit the insulating construction and solar panel. It should be understood that there is no intention to limit the insulating construction and solar panel to the specific form disclosed; rather, it is to cover all modifications, alternative constructions, and equivalents falling within the spirit and scope of the insulating construction and solar panel as defined in the claims. For example, while the exemplary embodiments illustrate a rectangular opening 17 in the insulating core 2 with a rectangular crystalline photovoltaic module 12 fitted therein, the insulating construction and solar panel may be used with other shaped openings and photovoltaic modules. Further, while the insulating construction and solar panel is not limited to use in roof constructions, it is expected that various embodiments of the insulating construction and solar panels will be particularly useful in such constructions. From the foregoing description, it will be apparent that various changes may be made without departing from the spirit and scope of the insulating construction and solar panel, which is defined by the following claims. The foregoing description should not be construed to limit its scope.

What is claimed is:

1. An insulating construction and solar panel comprising:
an insulating core having a top surface and a bottom surface, said insulating core defining at least one opening;
a rigid skin covering said top surface, said rigid skin having a first edge and a second edge, said rigid skin defining a ridge extending along said first edge, said rigid skin further defining a channel extending along said second edge;
a crystalline photovoltaic module fitted within said opening; said crystalline photovoltaic module having an outer surface and an inner surface; and
a translucent pane covering said outer surface, said translucent pane being sealed to said rigid skin such that said outer surface of said crystalline photovoltaic module is protected from environmental elements;
whereby said insulating construction and solar panel is configured to connect to a second insulating construction and solar panel having a second ridge by interconnecting said channel to said second ridge;
whereby said insulating construction and solar panel is further configured to connect to a third insulating construction and solar panel having a third channel by interconnecting said ridge to said third channel; and
whereby said insulating construction and solar panel is configured for use in forming insulated constructed surfaces while transmitting solar-generated energy.

2. The insulating construction and solar panel of claim 1, further comprising an adjustable insulating shutter connected to said insulating core; said adjustable insulating shutter being configured so as to be selectively movable from a closed position in which said inner surface is covered to at least one open position in which said inner surface is at least partially uncovered; said adjustable insulating shutter being further configured so as to be selectively movable from said at least one open position to said closed position; whereby, when said adjustable insulating shutter is positioned in said closed position, said inner surface is insulated, and whereby, when said adjustable insulating shutter is positioned in one of said open positions, said inner surface is at least partially exposed.

3. The insulating construction and solar panel of claim 2, wherein said adjustable insulating shutter is pivotally connected to said insulating core, said adjustable insulating shutter being configured to as to be selectively pivotally moved from said closed position to said at least one open position and selectively pivotally moved from said at least one open position to said closed position.

4. The insulating construction and solar panel of claim 1, further comprising
an adjustable insulating shutter connected to said insulating core, said adjustable insulating shutter being configured so as to be movable from a closed position in which said inner surface is covered to at least one open position in which said inner surface is at least partially uncovered, said adjustable insulating shutter being further configured so as to be movable from said at least one open position to said closed position;
a temperature sensor configured to detect the temperature of said crystalline photovoltaic module;
an actuator configured to move said adjustable insulating shutter to said closed position when said temperature sensor detects that said crystalline photovoltaic module's temperature is lower than a pre-determined minimum temperature;
said actuator being further configured to move said adjustable insulating shutter to at least one of said open positions when said temperature sensor detects that said crystalline photovoltaic module's temperature is greater than a pre-determined maximum temperature;
whereby when said crystalline photovoltaic module's temperature is lower than said pre-determined minimum temperature, said adjustable insulating shutter will be moved so as to be positioned to provide insulation to said inner surface; and
whereby when said crystalline photovoltaic module's temperature is greater than said pre-determined maximum temperature, said adjustable insulating shutter will be moved so as to be positioned to expose said inner surface and allow venting thereto.

5. The insulating construction and solar panel of claim 1, wherein said crystalline photovoltaic module is fitted within said opening such that said outer surface of said crystalline photovoltaic module is essentially flush with said top surface of said insulating core.

6. The insulating construction and solar panel of claim 1, wherein said crystalline photovoltaic module is fitted within said opening such that said outer surface of said crystalline photovoltaic module is essentially flush with said rigid skin.

7. The insulating construction and solar panel of claim 1, wherein said crystalline photovoltaic module is fitted within said opening so as to be recessed within said insulating core such that said outer surface of said crystalline photovoltaic module is not essentially flush with said to surface of said insulating core.

8. The insulating construction and solar panel of claim 1, wherein said crystalline photovoltaic module is fitted within said opening such that said inner surface of said crystalline photovoltaic module is recessed within said insulating core such that said inner surface is not flush with said bottom surface and defines an open volume.

9. The insulating construction and solar panel of claim 8, further comprising an adjustable insulating shutter connected to said insulating core; said adjustable insulating shutter being configured so as to be selectively movable from a closed position in which said inner surface is covered and in which said adjustable insulating shutter fully occupies said open volume to at least one open position in which said inner surface is at least partially uncovered; said adjustable insulating shutter being further configured so as to be selectively movable from said at least one open position to said closed position; whereby, when said adjustable insulating shutter is positioned in said closed position, said inner surface is insulated, and whereby, when said adjustable insulating shutter is positioned in one of said open positions, said inner surface is at least partially exposed.

10. The insulating construction and solar panel of claim 9, wherein said adjustable insulating shutter comprises a shutter top surface and a shutter bottom surface, wherein when said adjustable insulating shutter is positioned in said closed position, said shutter bottom surface is essentially flush with said bottom surface of said insulating core.

11. An insulating construction and solar panel comprising for warm environments comprising:
an insulating core having a top surface and a bottom surface, said insulating core defining at least one opening;
a rigid skin covering said top surface, said rigid skin having a first edge and a second edge, said rigid skin defining a ridge extending along said first edge, said rigid skin further defining a channel extending along said second edge, said ridge configured to interconnect with a second channel of a second insulating construction panel, said channel configured to interconnect with a third ridge of a third insulating construction panel;
a crystalline photovoltaic module fitted within said opening; said crystalline photovoltaic module having an outer surface and an inner surface; and
a translucent pane covering said outer surface;
whereby said insulating construction and solar panel is configured to connect to said second insulating construction panel having said second channel by interconnecting said ridge and said second channel;
whereby said insulating construction and solar panel is configured to connect to said third insulating construction panel having said third ridge by interconnecting said channel and said third ridge; and
whereby at least the majority of said inner surface is exposed.

12. An insulating construction and solar panel comprising for cool environments comprising:
an insulating core having a top surface and a bottom surface;
a rigid skin covering said top surface, said rigid skin having a first edge and a second edge, said rigid skin defining a ridge extending along said first edge, said rigid skin further defining a channel extending along said second edge, said ridge configured to interconnect with a second channel of a second insulating construction panel, said channel configured to interconnect with a third ridge of a third insulating construction panel;
a crystalline photovoltaic module fitted within said insulating core, said crystalline photovoltaic module having an outer surface and an inner surface; said crystalline photovoltaic module being situated within said insulating core such that at least the majority of said outer surface is not covered by said insulating core and such that said inner surface is covered by said insulating core; and
a translucent pane covering said outer surface;
whereby said insulating construction and solar panel is configured to connect to said second insulating construction panel having said second channel by interconnecting said ridge and said second channel; and
whereby said insulating construction and solar panel is configured to connect to said third insulating construction panel having said third ridge by interconnecting said channel and said third ridge.
